(19) United States
(12) Patent Application Publication
(10) Pub. No.: US 2020/0274048 A1
(43) Pub. Date: Aug. 27, 2020

(54) SWITCHING DEVICE USING ELECTRON SHUTTLE

(71) Applicant: KOREA INSTITUTE OF SCIENCE AND TECHNOLOGY, Seoul (KR)

(72) Inventors: Chulki KIM, Seoul (KR); Jae Hun KIM, Seoul (KR); Taikjin LEE, Seoul (KR); Minah SEO, Seoul (KR); Donggeun LEE, Seoul (KR)

(21) Appl. No.: 16/666,401

(22) Filed: Oct. 29, 2019

(30) Foreign Application Priority Data
Feb. 22, 2019 (KR) 10-2019-0021325

(51) Int. Cl. H01L 39/10; H01L 39/22

(52) U.S. Cl. CPC H01L 39/10; H01L 39/221

(57) ABSTRACT

According to one aspect of the present invention, a switching device using an electron shuttle includes a substrate, a center portion fixed onto the substrate, a first wing portion extending from the center portion in a first direction and spaced apart from the substrate, a second wing portion extending from the center portion in a second direction and spaced apart from the substrate, a conductive first electron shuttle connected to the first wing portion and disposed to be spaced apart from the substrate, and a conductive second electron shuttle connected to the second wing portion and disposed to be spaced apart from the substrate.

### CROSS-REFERENCE TO RELATED APPLICATION(S)

This application claims the benefit under 35 USC § 119(a) of Korean Patent Application No. 10-2019-0021325, filed on Feb. 22, 2019, in the Korean Intellectual Property Office, the entire disclosure of which is incorporated herein by reference for all purposes.

### BACKGROUND

### 1. Field

The following description relates to an electron device, and more specifically, a switching device using an electron shuttle.

### 2. Description of Related Art

As the worldwide information industry environment has changed into the Internet of Things (IoT) or wearable environment and technologies, such as artificial intelligence (AI) and autonomous driving vehicles are becoming common, development of semiconductor devices and computing technologies to efficiently process large-capacity data at low power is required.

Conventional switching devices widely used in such semiconductor devices and computing technologies use transistors implemented as integrated circuits. Such transistors are highly integrated using semiconductor processes, thereby enabling implementation of various logic circuits, operation circuits, computer circuits, or memory circuits. However, transistors in conventional integrated circuits face scaling limitations because they have thermoelectric emission-based physical operating characteristics. In addition, these transistors are affected by various factors causing carrier movement, for example, changes in radiation or temperature, thereby causing malfunction.

Thus, switching devices using an electron shuttle based on nanoscale dynamics have recently been developed.

### PRIOR ART DOCUMENT

### Patent Document

U.S. Pat. No. 6,946,693 (registered on Sep. 20, 2005)

### SUMMARY

In view of the foregoing problems, the present invention is to provide a switching device using an electron shuttle which is operable in a poor environment, such as high temperature. However, the problems sought to be solved by the present invention are illustrative and the scope of the present invention is not limited thereto.

According to one general aspect of the present invention, a switching device using an electron shuttle includes a substrate, a center portion fixed onto the substrate, a first wing portion extending from the center portion in a first direction and spaced apart from the substrate, a second wing portion extending from the center portion in a second direction and spaced apart from the substrate, a conductive first electron shuttle connected to the first wing portion and disposed to be spaced apart from the substrate, and a conductive second electron shuttle connected to the second wing portion and disposed to be spaced apart from the substrate, wherein a part of at least one of the center portion, the first wing portion, and the second wing portion includes a conductive material such that the first electron shuttle and the second electron shuttle are electrically insulated from each other and wherein the first electron shuttle and the second electron shuttle are mechanically connected to each other via the center portion, the first wing portion, and the second wing portion and are capable of pivotal movement around the center portion as a pivotal axis in opposite directions from each other, and hence when one of the first electron shuttle and the second electron shuttle oscillates, the other oscillates in an interlocked manner.

The switching device may further include a protrusion portion interposed between the substrate and the center portion such that the first wing portion, the second wing portion, the first electron shuttle, and the second electron shuttle are spaced apart from the substrate.

The switching device may further include a first drain portion and a second source portion that are disposed on and spaced apart from both sides of the first electron shuttle in a direction crossing the first wing portion, wherein when the first electron shuttle oscillates, electrons are transferred from the first source portion to the first drain portion through the first electron shuttle.

As the first electron shuttle oscillates once, one electron may be transferred from the first source portion to the first drain portion.

When current is applied between the first drain portion and the first source portion, the first electron shuttle may oscillate, and as the first electron shuttle oscillates, the second electron shuttle may oscillate around the center portion as a pivotal axis in conjunction with the first electron shuttle.

The switching device may further include a second drain portion and a second source portion that are disposed on and spaced apart from both sides of the second electron shuttle in a direction crossing the second wing portion, wherein when the second electron shuttle oscillates, electrons are transferred from the second source portion to the second drain portion through the second electron shuttle.

When current is applied between the second drain portion and the second source portion, the second electron shuttle may oscillate, and as the second electron shuttle oscillates, the first electron shuttle may oscillate around the center portion as a pivotal axis in conjunction with the second electron shuttle.

When the second electron shuttle oscillates once, one electron may be transferred from the second source portion to the second drain portion.

The center portion, the first wing portion, and the second wing portion may include an insulating material.

The first direction and the second direction may be opposite to each other.

According to another general aspect of the present invention, a switching device using an electron shuttle includes a substrate, a center portion fixed onto the substrate, a first wing portion and a second wing portion that expend from the center portion in each direction and are spaced apart from the substrate, a conductive first electron shuttle connected to the first wing portion and disposed to be spaced apart from the substrate, a first drain portion and a first source portion that are disposed on and spaced apart from both sides of the first electron shuttle in a direction crossing the first wing portion, a conductive second electron shuttle connected to the second wing portion and disposed to be spaced apart from the substrate, and a second drain portion and a second source portion that are disposed on and spaced apart from both sides of the second electron shuttle in a direction crossing the second wing portion, wherein the first electron shuttle and the second electron shuttle are electrically insulated from and mechanically connected to each other through the center portion, the first wing portion, and the second wing portion and are capable of pivotal movement around the center portion as a pivotal axis in opposite directions from each other, and hence when one of the first electron shuttle and the second electron shuttle oscillates, the other oscillates in an interlocked manner.

Other features and aspects will be apparent from the following detailed description, the drawings, and the claims.

### BRIEF DESCRIPTION OF THE DRAWINGS

FIG. 1 is a schematic perspective view showing a switching device according to one embodiment of the present invention. FIG. 2 is a schematic cross-sectional view taken from II-II cross section of the switching device of FIG. 1.

FIG. 3 is a schematic cross-sectional view showing a switching device according to another embodiment of the present invention.

FIG. 4 is a schematic perspective view showing a switching device according to another embodiment of the present invention.

FIG. 5 is a schematic cross-sectional view taken from V-V cross section of the switching device of FIG. 4.

FIG. 6 is a schematic cross-sectional view taken from VI-VI cross section of the switching device of FIG. 4.

### DESCRIPTION OF REFERENCE NUMERALS

100, 100a, 100b: switching device

105: substrate

110: protrusion portion

115: center portion

120: first wing portion

125: second wing portion

130, 130a: first electron shuttle

135, 135a: second electron shuttle

140: first drain portion

145: first source portion

150: second drain portion

155: second source portion

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

Hereinafter, the present invention will be described in detail by explaining embodiments of the invention with reference to the attached drawings. The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the sizes of elements may be exaggerated or reduced for convenience of explanation.

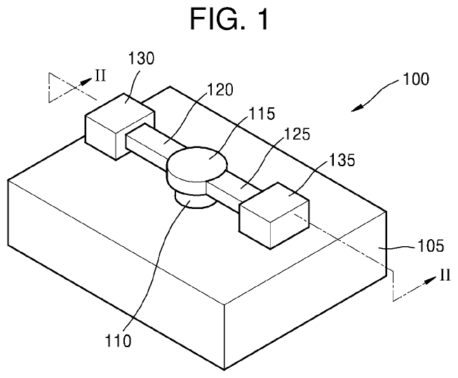

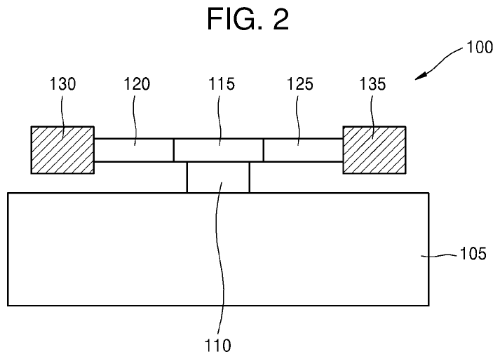

FIG. 1 is a schematic perspective view showing a switching device 100 according to one embodiment of the present invention and FIG. 2 is a schematic cross-sectional view taken from II-II cross section of the switching device 100 of FIG. 1.

Referring to FIGS. 1 and 2, the switching device 100 may include a substrate 105, a center portion 115, a first wing portion 120, a second wing portion 125, a first electron shuttle 130, and a second electron shuttle 135.

The substrate 105 may form an overall support structure in the switching device 100. The substrate 105 may include a semiconductor material or an electrical insulation material. For example, the substrate 105 may include an appropriate semiconductor material, for example, silicon (Si), germanium (Ge), SiGe, SiC, GaAs, InP, GaP, GaN, ZnSE, or the like. In another example, the substrate 105 may include a structure in which an insulating layer and a semiconductor layer are stacked atop each other. For example, the substrate 105 may include a laminated substrate having a semiconductor-on-insulator (SOI) structure, such as, a semiconductor/insulating layer/semiconductor structure.

The center portion 115 may be fixed onto the substrate 105. For example, a protrusion portion 110 is interposed between the substrate 105 and the center portion 115 so that the center portion 115 is fixed to the substrate 105 through the protrusion portion 110 and a structure connected to the center portion 115 may be spaced apart from the substrate 105.

The first wing portion 120 may extend from the center portion 115 in a first direction and may be provided in such a manner to be spaced apart from the substrate 105. For example, the first wing portion 120 may be connected to one side of the center portion 115 in the first direction and may not be in direct contact with the substrate 105.

The second wing portion 125 may extend from the center portion 115 in a second direction and may be provided in such a manner to be spaced apart from the substrate 105. For example, the second wing portion 125 may be connected to other side of the center portion 115 in the second direction and may not be in direct contact with the substrate 105.

In a more detailed example, the first wing portion 120 and the second wing portion 125 may be connected to each side of the center portion 115. In this case, the first direction and the second direction may be opposite to each other and the first wing portion 120, the center portion 115, and the second wing portion 125 may be disposed on substantially the same line.

A conductive first electron shuttle 130 may be connected to the first wing portion 120 and disposed to be spaced apart from the substrate 105. For example, the first electron shuttle 130 may be connected to a side of the first wing portion 120, which is opposite to the side connected to the center portion 115 and may not be in direct contact with the substrate 105. Accordingly, the first wing portion 120 and the first electron shuttle 130 may be sequentially connected to the center portion 115 along the first direction from the center portion 115.

A conductive second electron shuttle 135 may be connected to the second wing portion 125 and disposed to be spaced apart from the substrate 105. For example, the second electron shuttle 135 may be connected to a side of the second wing portion 125, which is opposite to the side connected to the center portion 115, and may not be in direct contact with the substrate 105. Accordingly, the second wing portion 125 and the second electron shuttle 135 may be sequentially connected to the center portion 115 along the second direction from the center portion 115.

The first electron shuttle 130 and the second electron shuttle 135 may include a conductive material capable of providing and accepting electrons. For example, the first electron shuttle 130 and the second electron shuttle 135 may include a conductor or a doped semiconductor material.

The first electron shuttle 130 and the second electron shuttle 135 may be electrically insulated from each other and transfer electrons independently of each other. Thus, a part of at least one of the center portion 115, the first wing portion 120, and the second wing portion 125, which connect the first electron shuttle 130 and the second electron shuttle 135, may include an insulating material such that the first electron shuttle 130 and the second electron shuttle 135 are electrically insulated from each other.

In some embodiments, the center portion 115, the first wing portion 120, and the second wing portion 125 may be made of an insulating material. In some embodiments, the center portion 115, the first wing portion 120, and the second wing portion 125 may be formed of the same material or be integrally provided.

According to one example of the above-described structure, as shown in FIG. 1, a pendulum structure may be formed in which the first wing portion 120 and the first electron shuttle 130 are sequentially connected in the first direction and the second wing portion 125 and the second electron shuttle 135 are connected in the second direction with the center portion 115 interposed between the first wing portion 120 and the second wing portion 125 on the substrate 105.

In the pendulum structure, the first electron shuttle 130 and the second electron shuttle 135 may be mechanically connected to each other via the first wing portion 120 and the second wing portion 125 and may be allowed for pivotal movement around the center portion 115 as the pivotal axis in opposite directions from each other. For example, when vibration is oscillated in one side with respect to the center portion 115 in a state where the center portion 115 is fixedly supported by the substrate 105, the vibration is transmitted to the other side with the center portion 115 as the pivotal axis. Thus, when one of the first electron shuttle 130 and the second electron shuttle 135 oscillates, the other shuttle oscillates in an interlocked manner

In the switching device 100 According to the present embodiment, the first electron shuttle 130 and the second electron shuttle 135 may serve to transfer electrons by means of mechanical motion under two predetermined structures. Furthermore, even when only one of the first electron shuttle 130 and the second electron shuttle 135 mechanically moves, torsional motion is possible using the center portion 115 as a pivotal axis so that the other shuttle moves in an interlocked manner. Therefore, when one of the first electron shuttle 130 and the second electron shuttle 135 is controlled, it is possible to control the other shuttle in an interlocked manner.

The switching device 100 is less affected by temperature or thermal emission characteristics as compared to a conventional device since the switching device 100 is based on mechanical movement without using thermionic emission. In addition, the switching device 100 having the torsional vibration structure according to the present embodiment may be applied in manufacturing various devices and circuits by using such interlocking electron transport movement and may thereby simplify structures of the devices and circuits.

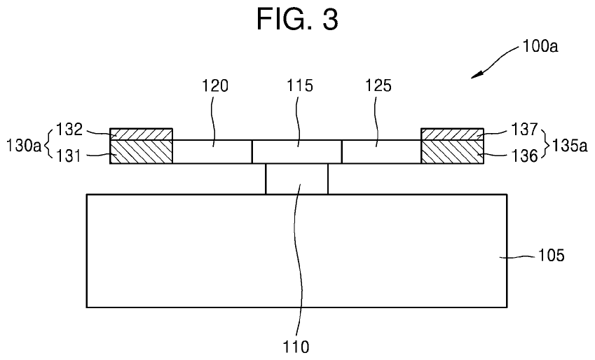

FIG. 3 is a schematic cross-sectional view showing a switching device 100a according to another embodiment of the present invention. The switching device 100a according to the present embodiment is obtained by modifying some components of the switching device 100 of FIGS. 1 and 2, and hence the two embodiments can be referenced to each other and duplicated descriptions in both embodiments will be omitted.

Referring to FIG. 3, a first electron shuttle 130a may include a first body portion 131 and a first conductive portion 132. For example, the first body portion 131 may be connected to a first wing portion 120 and the first conductive portion 132 may be stacked on the first body portion 131.

A second electron shuttle 135a may include a second body portion 136 and a second conductive portion 137. For example, the second body portion 136 may be connected to a second wing portion 125 and the second conductive portion 137 may be stacked on the second body portion 136.

For example, the first body portion 131 and the second body portion 135 may include an insulating material. In some examples, the first body portion 131 may be made of the same material as that of the first wing portion 120 or be provided integrally with the first wing portion 120, and the second body portion 135 may be made of the same material as that of the second wing portion 125 or be provided integrally with the second wing portion 125.

The first conductive portion 132 and the second conductive portion 137 may include a conductive material capable of providing and accepting electrons. For example, the first conductive portion 132 and the second conductive portion 137 may include a conductor or a doped semiconductor material.

Meanwhile, in a modified example of the present embodiment, the first body portion 131 may be included in the first wing portion 120 and the first electron shuttle 130a may be construed as referring to the first conductive portion 132. Similarly, the second body portion 136 may be included in the second wing portion 125 and the second electron shuttle 135a may be construed as referring to the second conductive portion 137.

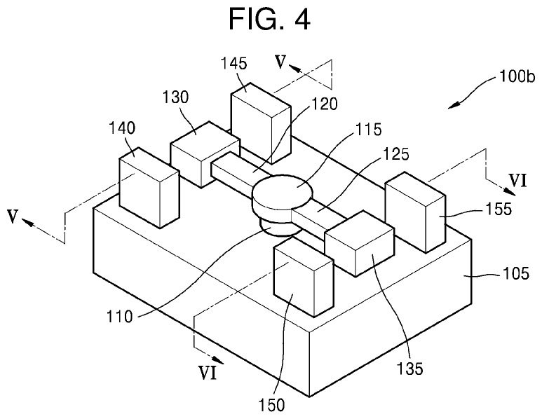

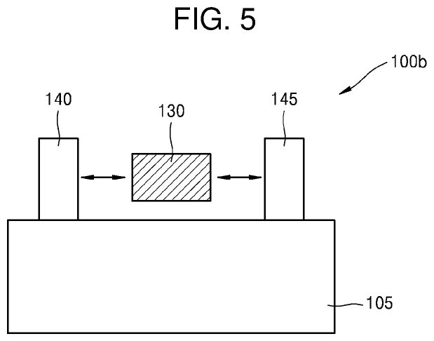

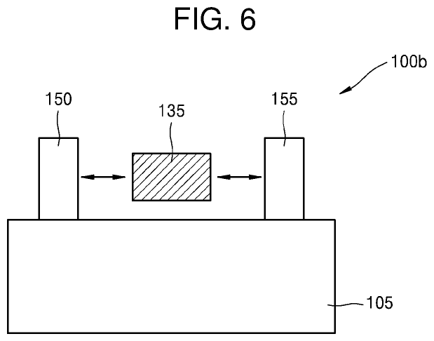

FIG. 4 is a schematic perspective view showing a switching device 100b according to another embodiment of the present invention, FIG. 5 is a schematic cross-sectional view taken from V-V cross section of the switching device 100b of FIG. 4, and FIG. 6 is a schematic cross-sectional view taken from VI-VI cross section of the switching device 100b of FIG. 4. The switching device 100b according to the present embodiment is obtained by adding some components to the switching device 100 of FIGS. 1 and 2, and thus duplicated descriptions in both embodiments will be omitted.

Referring to FIGS. 4 to 6, the switching device 100b may further include a first drain portion 140 and a first source portion 145 that are disposed on and spaced apart from both sides of a first electron shuttle 130 in a direction crossing a first wing portion 120. For example, the first drain portion 140 may include a conductor and/or a doped semiconductor material capable of receiving electrons from the first electron shuttle 130 and transferring the electrons and the first source portion 145 may include a conductor and/or a doped semiconductor material capable of transferring to provide electrons to the first electron shuttle 130.

It has been already reported that when direct current (DC) power or alternating current (AC) power of a predetermined magnitude or more is applied to the first drain portion 140 and the first source portion 145 in the above switching device 100b, electron transfer due to tunneling is possible between the first electron shuttle 130 and the first drain portion 140 and between the first electron shuttle 130 and the first source portion 145. Furthermore, due to self-excitation phenomenon, when the voltage difference between the first drain portion 140 and the first source portion 145 is greater than or equal to a threshold voltage, the oscillation amplitude of the first electron shuttle will increase exponentially until a balance between dissipated and absorbed energy is achieved and the system reaches a stable self-oscillating regime.

In addition, it is known that single-electron transport is possible according to a Coulomb blockade phenomenon as a Coulomb interaction between the first electron shuttle 130 and the first drain portion 140 and between the first electron shuttle 130 and the first source portion 145. Accordingly, as the first electron shuttle 130 oscillates once, one electron may be transferred from the first source portion 145 to the first drain portion 140.

Accordingly, when the first electron shuttle 130 oscillates between the first drain portion 140 and the first source portion 145, an operation of transferring an electron from the first source portion 145 to the first drain portion 140 through the first electron shuttle 130 is repeated so that a current can flow from the first drain portion 140 to the first source portion 145.

Furthermore, the switching device 100b may further include a second drain portion 150 and a second source portion 155 that are disposed on and spaced apart from both sides of a second electron shuttle 135 in a direction crossing a second wing portion 125. For example, the second drain portion 150 may include a conductor and/or a doped semiconductor material capable of receiving electrons from the second electron shuttle 135 and transferring the electron, and the second source portion 155 may include a conductor and/or a doped semiconductor material capable of transferring to provide electrons to the second electron shuttle 135.

In the above switching device 100b, when a DC or AC power of a predetermined magnitude or more is applied between the second drain portion 150 and the second source portion 155, electron transfer between the second electron shuttle 135 and the second drain portion 150 and between the second electron shuttle 135 and the second source portion 155 is possible as described above. Furthermore, due to self-excitation phenomenon, when the voltage difference between the second drain portion 150 and the second source portion 155 is greater than or equal to a threshold voltage, the oscillation amplitude of the second electron shuttle will increase exponentially until a balance between dissipated and absorbed energy is achieved and the system reaches a stable self-oscillating regime.

In addition, single-electron transport is possible according to a Coulomb blockade phenomenon as a Coulomb interaction between the second electron shuttle 135 and the second drain portion 150 and between the second electron shuttle 135 and the second source portion 155. Accordingly, as the second electron shuttle 135 oscillates once, one electron may be transferred from the second source portion 155 to the second drain portion 150.

Thus, when the second electron shuttle 135 oscillates between the second drain portion 150 and the second source portion 155, an operation of transferring an electron from the second source portion 155 to the second drain portion 150 through the second electron shuttle 135 is repeated so that a current can flow from the second drain portion 150 to the second source portion 155.

In the above-described switching device 100b, the electron transfer and the control of current through the oscillation of the first electron shuttle 130 and the second electron shuttle 135 may be optional. For example, when power is applied between the first drain portion 140 and the first source portion 145, the first electron shuttle 130 may be oscillated. Accordingly, when electrons move from the first source portion 145 to the first drain portion 140, current may flow in the opposite direction to the movement of the electrons. Furthermore, as the first electron shuttle 130 oscillates, the second electron shuttle 135 may oscillate around a center portion 115 as a pivotal axis in conjunction with the first electron shuttle 130. Accordingly, as electrons are transferred from the second source portion 155 to the second drain portion 150, current may flow in the opposite direction of the transfer of electrons.

In another example, when power is applied between the second drain portion 150 and the second source portion 155, the second electron shuttle 135 may oscillate. Accordingly, as electrons are transferred from the second source portion 155 to the second drain portion 150, current may flow in the opposite direction to the transfer of electrons. Moreover, as the second electron shuttle 135 oscillates, the first electron shuttle 130 may oscillate around the center portion 115 as a pivotal axis in conjunction with the second electron shuttle 135. Accordingly, when electrons are transferred from the first source portion 145 to the first drain portion 140, current may flow in the opposite direction to the transfer of electrons.

In the switching device 100b, the magnitude of current flowing from the first drain portion 140 to the first source portion 145 and the magnitude of current flowing from the second drain portion 150 to the second source portion 155 may be controlled by adjusting the magnitude of voltage to be applied for oscillation, oscillation frequencies of the first electron shuttle 130 and the second electron shuttle 135, and/or transport distances of the first electron shuttle 130 and the second electron shuttle 135.

Optionally, in the switching device 100b, current may be additionally controlled by adjusting Fermi levels of the first electron shuttle 130 and the second electron shuttle 135. For example, Fermi levels of the first electron shuttle 130 and the second electron shuttle 135 may be adjusted by applying a voltage to the first electron shuttle 130 and the second electron shuttle 135.

Hence, according to the structure of the switching device 100b in accordance with the present embodiment, one of the first electron shuttle 130 and the second electron shuttle 135 is controlled using torsional pendulum movement, so that the other shuttle may be controlled in an interlocked manner When such interlocking control is used, it is possible to implement various integrated circuits and application devices with a simple structure.

On the other hand, in the switching device 100b, the first electron shuttle 130 and the second electron shuttle 135 may be modified to the first electron shuttle 130a and the second electron shuttle 135 in the switching device 100a of FIG. 3.

The switching devices 100, 100a, and 100b according to the embodiments described above use a mechanical electron transfer method, and hence are operable in an extreme environment, such as a high temperature environment, a low temperature environment, or an electromagnetic pulse (EMP) environment. In addition, the switching devices 100, 100a, and 100b are applicable to a device technology using superconductor material for control of Cooper-pair transport.

The switching device according to the embodiments of the present invention as described above uses a mechanical electron transfer method, and hence is operable in an extreme environment, such as a high temperature environment, a low temperature environment, or an EMP environment. Also, the switching device is applied in manufacturing various devices and circuits by using interlocking electron transport movement and may thereby simplify structures of the devices and circuits. In addition, the switching device is applicable to a device technology using superconductor material for control of Cooper-pair transport. However, the scope of the present invention is not limited to these effects.

A number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A switching device using an electron shuttle, the switching device comprising:
a substrate;
a center portion fixed onto the substrate;
a first wing portion extending from the center portion in a first direction and spaced apart from the substrate;
a second wing portion extending from the center portion in a second direction and spaced apart from the substrate;
a conductive first electron shuttle connected to the first wing portion and disposed to be spaced apart from the substrate; and
a conductive second electron shuttle connected to the second wing portion and disposed to be spaced apart from the substrate,
wherein a part of at least one of the center portion, the first wing portion, and the second wing portion includes a conductive material such that the first electron shuttle and the second electron shuttle are electrically insulated from each other and
wherein the first electron shuttle and the second electron shuttle are mechanically connected to each other via the center portion, the first wing portion, and the second wing portion and are capable of pivotal movement around the center portion as a pivotal axis in opposite directions from each other, and hence when one of the first electron shuttle and the second electron shuttle oscillates, the other oscillates in an interlocked manner.

2. The switching device of claim 1, further comprising a protrusion portion interposed between the substrate and the center portion such that the first wing portion, the second wing portion, the first electron shuttle, and the second electron shuttle are spaced apart from the substrate.

3. The switching device of claim 1, further comprising:
a first drain portion and a second source portion that are disposed on and spaced apart from both sides of the first electron shuttle in a direction crossing the first wing portion,
wherein when the first electron shuttle oscillates, electrons are transferred from the first source portion to the first drain portion through the first electron shuttle.

4. The switching device of claim 3, wherein as the first electron shuttle oscillates once, one electron is transferred from the first source portion to the first drain portion.

5. The switching device of claim 3, wherein when current is applied between the first drain portion and the first source portion, the first electron shuttle oscillates and as the first electron shuttle oscillates, the second electron shuttle oscillates around the center portion as a pivotal axis in conjunction with the first electron shuttle.

6. The switching device of claim 1, further comprising:
a second drain portion and a second source portion that are disposed on and spaced apart from both sides of the second electron shuttle in a direction crossing the second wing portion,
wherein when the second electron shuttle oscillates, electrons are transferred from the second source portion to the second drain portion through the second electron shuttle.

7. The switching device of claim 6, wherein when current is applied between the second drain portion and the second source portion, the second electron shuttle oscillates, and as the second electron shuttle oscillates, the first electron shuttle oscillates around the center portion as a pivotal axis in conjunction with the second electron shuttle.

8. The switching device of claim 7, wherein when the second electron shuttle oscillates once, one electron is transferred from the second source portion to the second drain portion.

9. The switching device of claim 1, wherein the center portion, the first wing portion, and the second wing portion include an insulating material.

10. The switching device of claim 1, wherein the first direction and the second direction are opposite to each other.

11. A switching device using an electron shuttle, the switching device comprising:
a substrate;
a center portion fixed onto the substrate;
a first wing portion and a second wing portion that expend from the center portion in each direction and are spaced apart from the substrate;
a conductive first electron shuttle connected to the first wing portion and disposed to be spaced apart from the substrate;
a first drain portion and a first source portion that are disposed on and spaced apart from both sides of the first electron shuttle in a direction crossing the first wing portion;
a conductive second electron shuttle connected to the second wing portion and disposed to be spaced apart from the substrate; and
a second drain portion and a second source portion that are disposed on and spaced apart from both sides of the second electron shuttle in a direction crossing the second wing portion,
wherein the first electron shuttle and the second electron shuttle are electrically insulated from and mechanically connected to each other through the center portion, the first wing portion, and the second wing portion and are capable of pivotal movement around the center portion as a pivotal axis in opposite directions from each other, and hence when one of the first electron shuttle and the second electron shuttle oscillates, the other oscillates in an interlocked manner.
